(19) United States
(12) Patent Application Publication
(10) Pub. No.: US 2025/0203778 A1
(43) Pub. Date: Jun. 19, 2025

(54) MULTI-DOCK PRINTED CIRCUIT BOARD

(71) Applicant: Weathered Security, LLC, Virginia Beach, VA (US)

(72) Inventor: Dale Robert Wooden, Virginia Beach, VA (US)

(73) Assignee: Weathered Security, LLC, Virginia Beach, VA (US)

(21) Appl. No.: 18/843,354

(22) PCT Filed: Mar. 3, 2023
(86) PCT No.: PCT/US2023/063688

§ 371 Date: Sep. 3, 2024

Related U.S. Application Data
(60) Provisional application No. 63/316,815, filed on Mar. 4, 2022.

(51) Int. Cl. H05K 1/14; H05K 1/18

(52) U.S. Cl. CPC H05K 1/142; H05K 1/183; H05K 2201/09036; H05K 2201/10189; H05K 2201/2027

(57) ABSTRACT

A printed circuit board (“PCB”) includes a PCB substrate comprising a conductive trace; a dock opening formed from a cutout extending through the PCB substrate; a securing rail coupled to the PCB substrate along at least one edge of the dock opening, the securing rail comprising at least one attachment point; at least one connector coupled to the PCB substrate; and a locking member coupleable to the securing rail at the at least one attachment point.

### CROSS-REFERENCE TO RELATED APPLICATIONS

This application is related to and claim priority benefits from U.S. Provisional Patent Application No. 63/316,815, filed on Mar. 4, 2022, entitled “MULTI-DOCK PRINTED CIRCUIT BOARD,” the entirety of which is hereby incorporated by reference.

### TECHNICAL FIELD

The present disclosure relates generally to circuit boards, and more specifically, but not by way of limitation, to circuit boards having multiple device docking locations.

### BACKGROUND

A printed circuit board (“PCB”) is a circuit board which plays a role of electrically connecting predetermined electronic components and has a predetermined wiring pattern formed thereon. Conventionally, the connectors are arranged so that the electronic components extend out from the PCB resulting in a large overall volume of the PCB and connected electronic components. Additionally, the electronic components are generally only connected to the PCB via the connector, which results in a loose, unstable connection between the connectors and the electronic components. In some instances, vibrations or other movements of the PCB may cause the electronic components to disconnect from the connectors entirely.

### SUMMARY

The terms “invention,” “the invention,” “this invention” and “the present invention” used in this patent are intended to refer broadly to all of the subject matter of this patent and the patent claims below. Statements containing these terms should be understood not to limit the subject matter described herein or to limit the meaning or scope of the patent claims below. Embodiments of the invention covered by this patent are defined by the claims below, not this summary. This summary is a high-level overview of various aspects of the invention and introduces some of the concepts that are further described in the Detailed Description section below. This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings and each claim.

Various examples are described for devices and systems for a circuit board having multiple device docking locations. One example device includes a printed circuit board (“PCB”) having a PCB substrate with a conductive trace; a dock opening formed from a cutout extending through the PCB substrate; a securing rail coupled to the PCB substrate along at least one edge of the dock opening, the securing rail comprising at least one attachment point; at least one connector coupled to the PCB substrate; and a locking member coupleable to the securing rail at the at least one attachment point.

One example system includes a portable electronics system having a printed circuit board (“PCB”) that includes a dock opening formed from a cutout extending through the PCB; a securing rail coupled to at least one edge of the dock opening; and at least one connector coupled to the PCB; an external device coupled to the at least one connector; and a locking member coupled to the securing rail, where the external device is coupled at least partially between the locking member and the at least one connector.

One example system includes a portable electronics system having a printed circuit board (“PCB”) that includes a PCB substrate having a conductive trace; a plurality of dock openings formed from a plurality of cutouts each extending through the PCB substrate; a plurality of securing rails, where each securing rail of the plurality of securing rails is coupled to at least one edge of at least one dock opening of the plurality of dock openings; and a plurality of connectors coupled to the PCB substrate, where each connector of the plurality of connectors is coupled to the PCB substrate at a docking end of one dock opening of the plurality of dock openings; a plurality of external devices coupled to the plurality of connectors; and a plurality of locking members coupled to the plurality of securing rails, where each external device of the plurality of external devices is coupled at least partially between a respective locking member and a respective connector.

These illustrative examples are mentioned not to limit or define the scope of this disclosure, but rather to provide examples to aid understanding thereof. Illustrative examples are discussed in the Detailed Description, which provides further description. Advantages offered by various examples may be further understood by examining this specification.

### BRIEF DESCRIPTION OF THE DRAWINGS

The accompanying drawings, which are incorporated into and constitute a part of this specification, illustrate one or more certain examples and, together with the description of the example, serve to explain the principles and implementations of the certain examples.

FIG. 1A is a top perspective view of a printed circuit board (“PCB”) according to certain embodiments of the present disclosure.

FIG. 1B is a bottom perspective view of the PCB of FIG. 1A.

FIGS. 2A and 2B are top views of the PCB of FIG. 1A.

FIG. 3 is a top view of the PCB of FIG. 1A without any electronic components coupled to the PCB.

FIG. 4 is a top view of a PCB with external devices connected to the PCB according to certain embodiments of the present disclosure.

FIG. 5 is a side perspective view of the PCB of FIG. 4.

### DETAILED DESCRIPTION

The subject matter of embodiments of the present invention is described here with specificity to meet statutory requirements, but this description is not necessarily intended to limit the scope of the claims. The claimed subject matter may be embodied in other ways, may include different elements or steps, and may be used in conjunction with other existing or future technologies. This description should not be interpreted as implying any particular order or arrangement among or between various steps or elements except when the order of individual steps or arrangement of elements is explicitly described.

As used herein, directional and spatial terms such as “right,” “left,” “top,” “bottom,” “front,” “rear,” “horizontal,” “vertical,” “horizontally,” “vertically,” and “upward” are not intended to be binding terms.

Certain aspects and features of the present disclosure relate to multi-dock printed circuit boards. The embodiments of the present disclosure described below are not intended to be exhaustive or to limit the disclosure to the precise forms described herein. Rather, the embodiments described herein are chosen so that a person of skill in the art can appreciate and understand the principles and practices of the present disclosure.

Embodiments are described herein in the context of substrates to which radios, universal serial bus (“USB”) dongles, and other devices may be docked, specifically docking to a printed circuit board (“PCB”) suitable for use in a portable electronics system. Those of ordinary skill in the art will realize that the following description is illustrative only and is not intended to be in any way limiting. Reference will now be made in detail to implementations of examples as illustrated in the accompanying drawings. The same reference indicators will be used throughout the drawings and the following description to refer to the same or like items.

In the interest of clarity, not all of the routine features of the examples described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another.

In an illustrative example, a docking PCB may be formed with eight docking stations formed with the docking PCB. Each docking station includes a cutout from the docking PCB and a connecting port positioned on the docking PCB at an end of the cutout. An electronic device may be plugged into the connecting port such that the electronic device occupies a portion of the cutout.

A stabilizing plate may be arranged at the end of the electronic device opposite to the end plugged into the connecting port. The stabilizing plate may have an opening through which a portion of the electronic device may extend. The stabilizing plate is slidable along rails extending the length of the edges of the cutout and coupled to the rails at a suitable location based on the USB device to be attached. Thus, the location of the coupling of the stabilizing plate along the rails may be determined based on the size of the electronic device and may be at any suitable point.

The docking PCB may also include stacking openings extending through the docking PCB at various locations that are engageable with stacking rods. These stacking rods may be inserted into the stacking openings such that multiple docking PCBs may be stacked on top of each other. The illustrative docking PCB enables multiple electronic devices to be stably and securely coupled to a single docking PCB and for the docking PCB to be coupled to a stack of one or more additional PCBs, which may provide processing or communications capabilities.

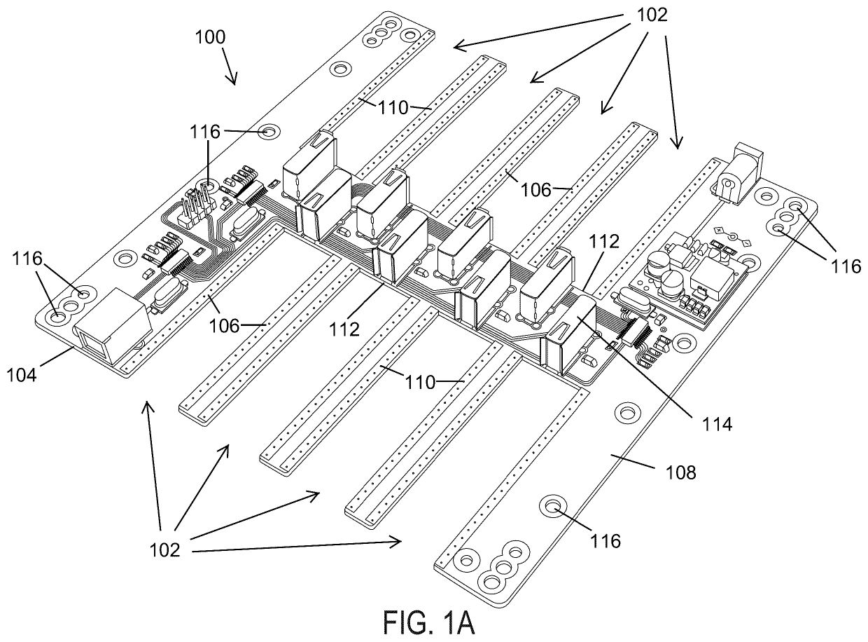

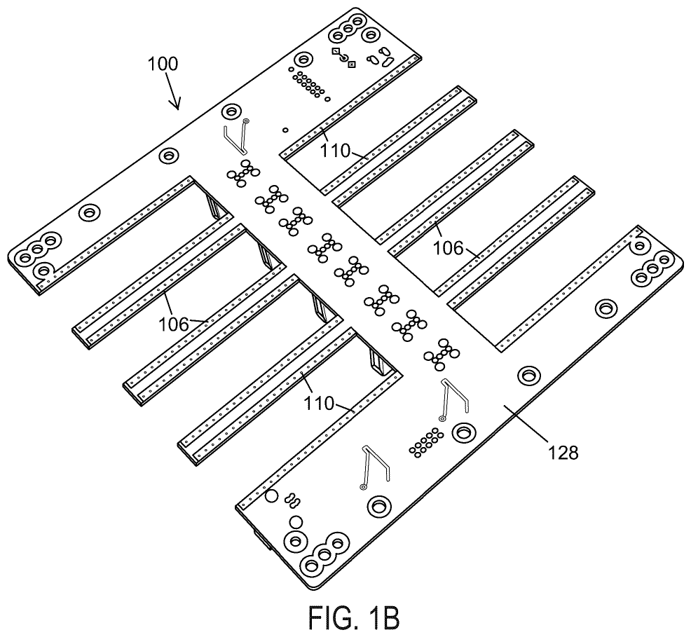

FIGS. 1A-5 show a docking PCB 100, according to certain embodiments. Referring now to FIGS. 1A-1B, FIG. 1A shows a top perspective view of an example docking PCB 100 and FIG. 1B shows a bottom perspective view of an example docking PCB 100. The docking PCB 100 is patterned with conductive traces that provide appropriate electrical paths interconnecting various electronic components.

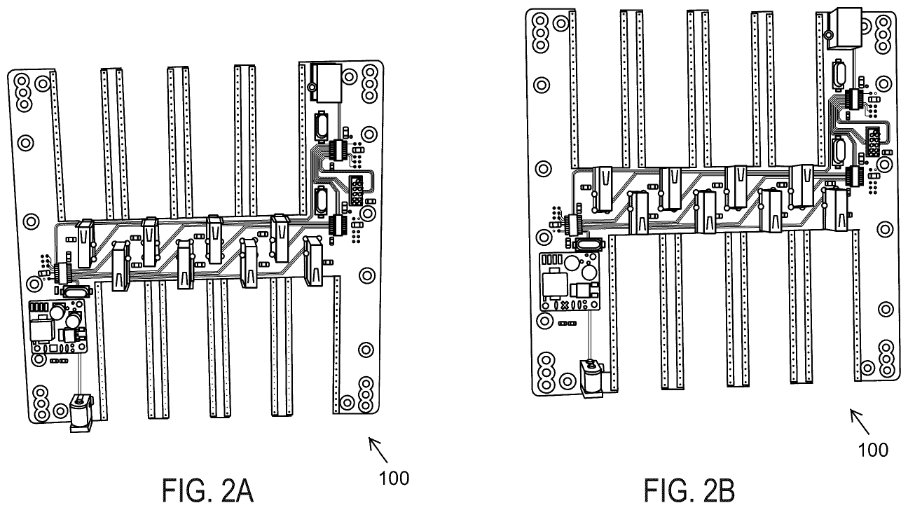

In some embodiments, the docking PCB 100 is substantially rectangular shaped. However, the docking PCB 100 may be any suitable shape, e.g., triangular, trapezoidal, circular, etc. Additionally, a length and a width of the docking PCB 100 may be substantially the same, as shown in FIGS. 2A-2B, or may be different. For example, both the length and width of the docking PCB 100 may be between 6 inches and 7 inches, may be between 5 inches and 8 inches, may be between 4 inches and 9 inches, etc. Where the length and width of the docking PCB 100 are not the same, the length may be between 6 inches and 7 inches, may be between 5 inches and 8 inches, may be between 4 inches and 9 inches, etc. and the width may be 6.5625 inches, may be between 6 inches and 7 inches, may be between 5 inches and 8 inches, may be between 4 inches and 9 inches, etc.

The docking PCB 100 includes at least one dock opening 102 extending through the docking PCB 100 so that the dock opening 102 forms a substantially rectangular shaped cutout along at least one edge 104 of the docking PCB 100. Any suitable number of dock openings 102 may be included along any number of edges 104 of the docking PCB 100 based on the size of the docking PCB 100. Additionally, the dock opening 102 may have any suitable width and length.

At least two securing rails 106 are attached to the docking PCB 100 along opposing edges of the at least one opening 102. In some embodiments, at least one securing rail 106 is attached to the docking PCB 100 along at least one edge of the at least one opening 102. Additionally, the at least one securing rail 106 may extend along multiple edges of the at least one opening 102. The securing rails 106 may be formed of metal, plastic, rubber, or any other suitable material. Each securing rail 106 may wrap around an edge of the docking PCB 100 from a first surface 108 of the docking PCB 100 to a second surface 128 of the docking PCB 100. The first surface 108 and the second surface 128 may be parallel to one another or may intersect one another to form a corner between the first surface 108 and the second surface 128.

Each securing rail 106 also includes at least one attachment point. In some embodiments, the at least one attachment point includes a plurality of securing openings 110 extending at least partially through each securing rail 106 at various locations along each securing rail 106. In certain embodiments, the docking PCB 100 may include securing openings that extend at least partially through the docking PCB 100 such that each substantially aligns with a corresponding securing opening 110 extending through the corresponding securing rail 106.

At a docking end 112 of at least one dock opening 102, at least one connector 114 is coupled to the docking PCB 100. In some embodiments, the connector 114 may be a USB port, including USB 2.0 or USB 3.0, or any other suitable port. The connector 114 may be electrically connected to the various other electronic components of the docking PCB 100 via the conductive traces extending throughout the docking PCB 100. As may be seen in FIGS. 1A and 1B, each dock opening 102 may have a corresponding connector 114 coupled to the docking PCB 100. Additionally, different types of ports may be used as connectors 114 at different dock openings 102 for a single docking PCB 100.

In some embodiments, the docking PCB 100 may include a plurality of stacking openings 116. Each stacking opening 116 may extend at least partially through the docking PCB 100 and may be positioned at any suitable location on the docking PCB 100. In some embodiments, a grommet may be inserted into the stacking openings 116. Additionally, at least one of the stacking opening 116 or the grommet may be threaded.

The stacking opening 116 may be engageable with a rod. The rod may have at least one end portion and a central portion. In some embodiments, the at least one end portion has a diameter that is smaller than a diameter of the central portion, and the change in diameter between the end portion and the central portion of the rod may form a ledge. Additionally, the at least one end portion of the rod may be threaded.

In certain embodiments, a first docking PCB 100 is stackable with at least one second docking PCB 100 using a plurality of the rods so that the first docking PCB 100 is arranged above the at least one second docking PCB 100. One of the at least one end portions of the rod may be insertable into one of the stacking openings 116 in the docking PCB 100. For example, a threaded end portion of the rod may be screwed into a threaded stacking opening 116. In further embodiments, the rods may be snap-fit or friction-fit within the stacking openings 116. Each rod may be insertable into a corresponding stacking opening 116 until the ledge of the rod abuts one of the first surface 108, the second surface 128, or the grommet.

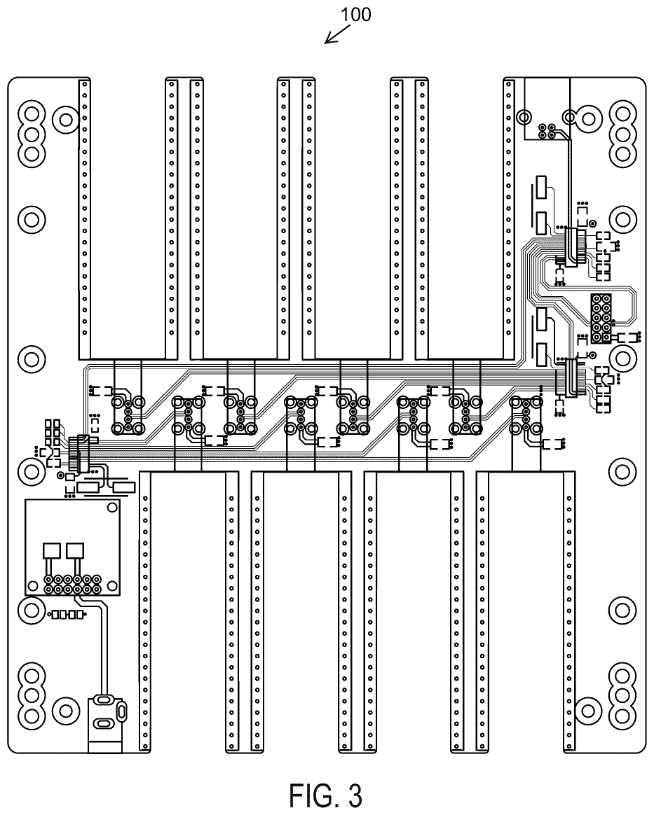

FIG. 3 shows a top view of the docking PCB 100 without any of the various electronic components coupled to the docking PCB 100.

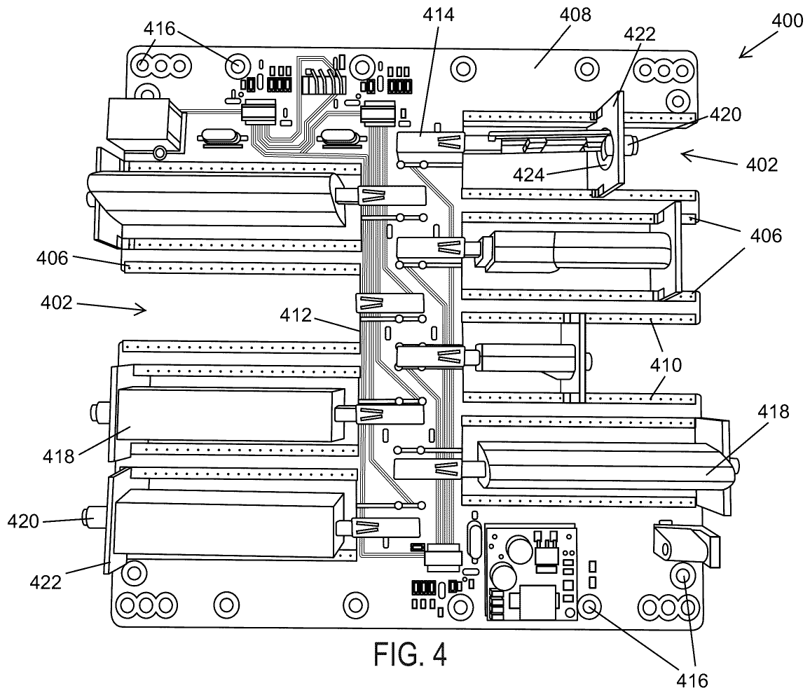

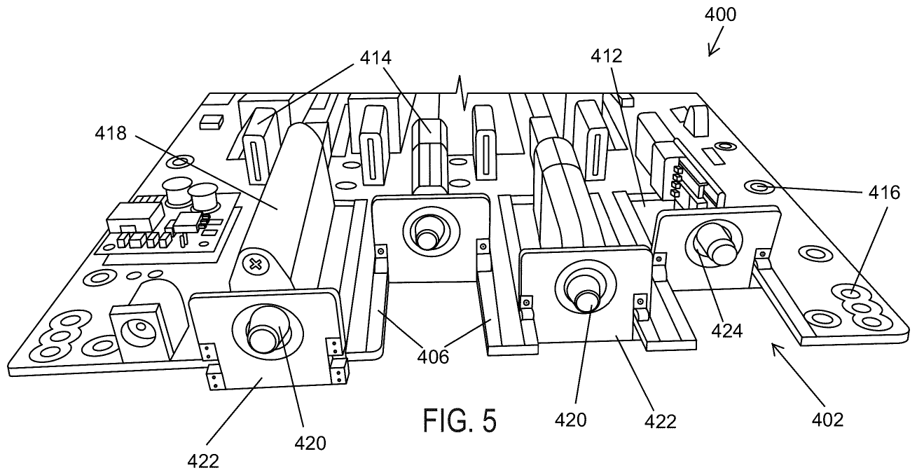

Referring now to FIGS. 4 and 5, FIGS. 4 and 5 show another docking PCB 400 according to certain embodiments. The docking PCB 400 may include the same or similar features, such as a plurality of dock openings 402, a plurality of securing rails 406, a first surface 408, a second surface, a plurality of securing openings 410 extending at least partially through the corresponding securing rail 406, a docking end 412, a plurality of connectors 414, and a plurality of stacking openings 416, as are described above in relation to FIGS. 1A and 1B.

At least one external device 418 may be connected to the docking PCB 400. The at least one external device 418 may be a radio, a USB dongle, or any other suitable device. The external devices 418 connected to the docking PCB 400 may all be of the same type, e.g., all radio devices, or may be a mix of multiple types, e.g., a radio device and a USB dongle.

Each external device 418 is connectable to at least one corresponding connector 414 that has a matching port to the external device 418. For example, a USB dongle may be inserted into a matching USB port. In some embodiments, the external device 418 may be sized to sit above the first surface 408 so that the external device 418 is not positioned within a respective dock opening 402. In further embodiments, the connector 414 is positioned so that the external device 418 is substantially in-line with the docking PCB 400 in the dock opening 402 when the external device 418 is coupled to the connector 414. For example, the external device 418 may be sized to extend past one or more of the first surface 408 or the second surface so that the external device 418 is positioned at least partially in a respective dock opening 402. Enabling the external devices 418 to be positioned in-line with the docking PCB 400 reduces the overall volume that the docking PCB 400 and connected external devices 418 occupy. Additionally, each external device 418 may include a stabilizing member 420. The stabilizing member 420 may extend from an end of the external device 418 that is opposite to the end connectable to the connector 414.

At least one locking mechanism 422 is used to stabilize and secure a respective external device 418 that is coupled to the docking PCB 400 during any movement or vibration of the docking PCB 400. In some embodiments, the at least one locking mechanism includes a stabilizing opening 424 extending at least partially through the locking mechanism 422.

The locking mechanism 422 may be coupled to at least one securing rail 406 using any suitable fastener, e.g., screws, nuts and bolts, snap-fit buttons, adhesive, etc. or coupling, e.g., snap-fit connection, friction-fit connection, welding, etc. the fastener and/or coupling may engage with at least one securing opening 410. When the locking mechanism 422 is coupled to the at least one securing rail 406, the external device 418 is positioned between the connector 414 and the locking mechanism 422. In some instances, the locking mechanism 422 may abut a portion of the external device 418. Additionally, when the locking mechanism 422 is coupled to the at least one securing rail 406, the stabilizing member 420 may engage with the locking mechanism 422 to further stabilize and secure the external device 418. For example, the stabilizing member 420 may extend at least partially through the stabilizing opening.

When coupling the locking mechanism 422 to the at least one securing rail 406, the at least one securing opening 410 that the fastener and/or coupling engage with may be selected based on the size of the external device 418 so that the external device 418 is securely coupled to the docking PCB 400. For example, a first locking mechanism 422 is coupled to the at least one securing rail 406 at a first distance from the connector where the first distance is based on a length of a first external device 418. A second locking mechanism 422 is coupled to the at least one second securing rail 406 at a second distance from the connector where the second distance is based on a length of the second external device 418. The coupling of the locking mechanism 422 to the at least one securing rail 406 provides customizable attachment points for the locking mechanism 422 based on the size of each individual external device 418 coupled to the respective connector 414.

The foregoing description of some examples has been presented only for the purpose of illustration and description and is not intended to be exhaustive or to limit the disclosure to the precise forms disclosed. Numerous modifications and adaptations thereof will be apparent to those skilled in the art without departing from the spirit and scope of the disclosure.

Reference herein to an example or implementation means that a particular feature, structure, operation, or other characteristic described in connection with the example may be included in at least one implementation of the disclosure. The disclosure is not restricted to the particular examples or implementations described as such. The appearance of the phrases “in one example,” “in an example,” “in one implementation,” or “in an implementation,” or variations of the same in various places in the specification does not necessarily refer to the same example or implementation. Any particular feature, structure, operation, or other characteristic described in this specification in relation to one example or implementation may be combined with other features, structures, operations, or other characteristics described in respect of any other example or implementation.

Use herein of the word “or” is intended to cover inclusive and exclusive OR conditions. In other words, A or B or C includes any or all of the following alternative combinations as appropriate for a particular usage: A alone; B alone; C alone; A and B only; A and C only; B and C only; and A and B and C.

In the following, further examples are described to facilitate the understanding of the invention (and in some aspects, features of an apparatus or system described in one or more of these examples may be utilized in a method described in one of the other examples or vice versa). These examples are not meant to be mutually exclusive, exhaustive, or restrictive; and the disclosure is not limited to these examples but rather encompasses all possible modifications and variations within the scope of the issued claims and their equivalents.

Example 1 is a printed circuit board (“PCB”), which may incorporate features of any of the subsequent example(s), comprising: a PCB substrate comprising a conductive trace; a dock opening formed from a cutout extending through the PCB substrate; a securing rail coupled to the PCB substrate along at least one edge of the dock opening, the securing rail comprising at least one attachment point; at least one connector coupled to the PCB substrate; and a locking member coupleable to the securing rail at the at least one attachment point.

Example 2 is the PCB of example(s) 1 or any preceding or subsequent example(s) or combination of examples, further comprising a second securing rail coupled to the PCB substrate along at least one second edge of the dock opening.

Example 3 is the PCB of example(s) 1 or any preceding or subsequent example(s) or combination of examples, wherein the PCB substrate comprises a first surface and a second surface, and the securing rail wraps around the at least one edge of the dock opening from the first surface to the second surface.

Example 4 is the PCB of example(s) 1 or any preceding or subsequent example(s) or combination of examples, wherein the at least one connector is coupled to the PCB substrate at a docking end of the dock opening.

Example 5 is the PCB of example(s) 1 or any preceding or subsequent example(s) or combination of examples, wherein an external device is coupleable to the at least one connector.

Example 6 is the PCB of example(s) 5 or any preceding or subsequent example(s) or combination of examples, wherein the external device is positioned at least partially within the dock opening.

Example 7 is the PCB of example(s) 5 or any preceding or subsequent example(s) or combination of examples, wherein the external device is coupleable at least partially between the locking member and the at least one connector.

Example 8 is the PCB of example(s) 7 or any preceding or subsequent example(s) or combination of examples, wherein the at least one attachment point is determined based on a size of the external device.

Example 9 is the PCB of example(s) 7 or any preceding or subsequent example(s) or combination of examples, wherein the external device comprises a stabilizing member that extends at least partially through the locking member when the external device is coupled between the locking member and the at least one connector.

Example 10 is a portable electronics system, which may incorporate features of any of the preceding or subsequent example(s), comprising: a printed circuit board (“PCB”) comprising: a dock opening formed from a cutout extending through the PCB; a securing rail coupled to at least one edge of the dock opening; and at least one connector coupled to the PCB; an external device coupled to the at least one connector; and a locking member coupled to the securing rail, wherein the external device is coupled at least partially between the locking member and the at least one connector.

Example 11 is the portable electronics system of example(s) 10 or any preceding or subsequent example(s) or combination of examples, wherein the PCB further comprises a second securing rail coupled to at least one second edge of the dock opening.

Example 12 is the portable electronics system of example(s) 10 or any preceding or subsequent example(s) or combination of examples, wherein the PCB comprises a first surface and a second surface, and the securing rail wraps around the at least one edge of the dock opening from the first surface to the second surface.

Example 13 is the portable electronics system of example(s) 10 or any preceding or subsequent example(s) or combination of examples, wherein the at least one connector is coupled to the PCB at a docking end of the dock opening.

Example 14 is the portable electronics system of example(s) 10 or any preceding or subsequent example(s) or combination of examples, wherein the external device is positioned at least partially within the dock opening.

Example 15 is the portable electronics system of example(s) 10 or any preceding or subsequent example(s) or combination of examples, wherein a position of the coupling of the locking member to the securing rail is determined based on a size of the external device.

Example 16 is the portable electronics system of example(s) 10 or any preceding or subsequent example(s) or combination of examples, wherein the external device comprises a stabilizing member that engages with the locking member.

Example 17 is the portable electronics system of example(s) 16 or any preceding or subsequent example(s) or combination of examples, wherein the locking member defines a stabilizing opening through which the stabilizing member at least partially extends.

Example 18 is the portable electronics system of example(s) 10 or any preceding or subsequent example(s) or combination of examples, where at least a portion of the locking member abuts a surface of the external device.

Example 19 is the portable electronics system of example(s) 10 or any preceding or subsequent example(s) or combination of examples, wherein the securing rail comprises at least one attachment point extending at least partially through the securing rail, and wherein the locking member is coupled to the securing rail at the at least one attachment point.

Example 20 is a portable electronics system, which may incorporate features of any of the preceding example(s), comprising: a printed circuit board (“PCB”) comprising: a PCB substrate comprising a conductive trace; a plurality of dock openings formed from a plurality of cutouts each extending through the PCB substrate; a plurality of securing rails, wherein each securing rail of the plurality of securing rails is coupled to at least one edge of at least one dock opening of the plurality of dock openings; and a plurality of connectors coupled to the PCB substrate, wherein each connector of the plurality of connectors is coupled to the PCB substrate at a docking end of one dock opening of the plurality of dock openings; a plurality of external devices coupled to the plurality of connectors; and a plurality of locking members coupled to the plurality of securing rails, wherein each external device of the plurality of external devices is coupled at least partially between a respective locking member and a respective connector.

Different arrangements of the components depicted in the drawings or described above, as well as components and steps not shown or described are possible. Similarly, some features and sub-combinations are useful and may be employed without reference to other features and sub-combinations. Embodiments of the invention have been described for illustrative and not restrictive purposes, and alternative embodiments will become apparent to readers of this patent. Accordingly, the present invention is not limited to the embodiments described above or depicted in the drawings, and various embodiments and modifications may be made without departing from the scope of the claims below.

That which is claimed is:

1. A printed circuit board (“PCB”) comprising:
a PCB substrate comprising a conductive trace;
a dock opening formed from a cutout extending through the PCB substrate;
a securing rail coupled to the PCB substrate along at least one edge of the dock opening, the securing rail comprising at least one attachment point;
at least one connector coupled to the PCB substrate; and
a locking member coupleable to the securing rail at the at least one attachment point.

2. The PCB of claim 1, further comprising a second securing rail coupled to the PCB substrate along at least one second edge of the dock opening.

3. The PCB of claim 1, wherein the PCB substrate comprises a first surface and a second surface, and the securing rail wraps around the at least one edge of the dock opening from the first surface to the second surface.

4. The PCB of claim 1, wherein the at least one connector is coupled to the PCB substrate at a docking end of the dock opening.

5. The PCB of claim 1, wherein an external device is coupleable to the at least one connector.

6. The PCB of claim 5, wherein the external device is positioned at least partially within the dock opening.

7. The PCB of claim 5, wherein the external device is coupleable at least partially between the locking member and the at least one connector.

8. The PCB of claim 7, wherein the at least one attachment point is determined based on a size of the external device.

9. The PCB of claim 7, wherein the external device comprises a stabilizing member that extends at least partially through the locking member when the external device is coupled between the locking member and the at least one connector.

10. A portable electronics system comprising:
a printed circuit board (“PCB”) comprising:
a dock opening formed from a cutout extending through the PCB;
a securing rail coupled to at least one edge of the dock opening; and
at least one connector coupled to the PCB;
an external device coupled to the at least one connector; and
a locking member coupled to the securing rail, wherein the external device is coupled at least partially between the locking member and the at least one connector.

11. The portable electronics system of claim 10, wherein the PCB further comprises a second securing rail coupled to at least one second edge of the dock opening.

12. The portable electronics system of claim 10, wherein the PCB comprises a first surface and a second surface, and the securing rail wraps around the at least one edge of the dock opening from the first surface to the second surface.

13. The portable electronics system of claim 10, wherein the at least one connector is coupled to the PCB at a docking end of the dock opening.

14. The portable electronics system of claim 10, wherein the external device is positioned at least partially within the dock opening.

15. The portable electronics system of claim 10, wherein a position of the coupling of the locking member to the securing rail is determined based on a size of the external device.

16. The portable electronics system of claim 10, wherein the external device comprises a stabilizing member that engages with the locking member.

17. The portable electronics system of claim 16, wherein the locking member defines a stabilizing opening through which the stabilizing member at least partially extends.

18. The portable electronics system of claim 10, where at least a portion of the locking member abuts a surface of the external device.

19. The portable electronics system of claim 10, wherein the securing rail comprises at least one attachment point extending at least partially through the securing rail, and wherein the locking member is coupled to the securing rail at the at least one attachment point.

20. A portable electronics system comprising:
a printed circuit board (“PCB”) comprising:
a PCB substrate comprising a conductive trace;
a plurality of dock openings formed from a plurality of cutouts each extending through the PCB substrate;
a plurality of securing rails, wherein each securing rail of the plurality of securing rails is coupled to at least one edge of at least one dock opening of the plurality of dock openings; and
a plurality of connectors coupled to the PCB substrate, wherein each connector of the plurality of connectors is coupled to the PCB substrate at a docking end of one dock opening of the plurality of dock openings;
a plurality of external devices coupled to the plurality of connectors; and
a plurality of locking members coupled to the plurality of securing rails, wherein each external device of the plurality of external devices is coupled at least partially between a respective locking member and a respective connector.
